(19) United States
(12) Patent Application Publication
(10) Pub. No.: US 2024/0341082 A1
(43) Pub. Date: Oct. 10, 2024

(54) 4F2 VERTICAL ACCESS TRANSISTOR WITH REDUCED FLOATING BODY EFFECT

(71) Applicant: Applied Materials, Inc., Santa Clara, CA (US)

(72) Inventors: Zhijun Chen, San Jose, CA (US); Fredrick Fishburn, Aptos, CA (US); Milan Pesic, Paoli, PA (US)

(73) Assignee: Applied Materials, Inc., Santa Clara, CA (US)

(21) Appl. No.: 18/620,296

(22) Filed: Mar. 28, 2024

Related U.S. Application Data
(60) Provisional application No. 63/495,028, filed on Apr. 7, 2023.
(60) Provisional application No. 63/601,064, filed on Nov. 20, 2023.

(51) Int. Cl. H10B 12/00

(52) U.S. Cl. CPC H10B 12/315; H10B 12/05; H10B 12/482; H10B 12/485

(57) ABSTRACT

The present technology includes vertical cell dynamic random-access memory (DRAM) array access transistors with improved hole distribution. The arrays include a plurality of bit lines arranged in a first horizontal direction and a plurality of word lines arranged in a second horizontal direction. The arrays include a plurality of channels extending in a vertical direction orthogonal to the first direction and the second horizontal direction, such that the plurality of bit lines intersect with a source/drain region of the plurality of channels, and the plurality of word lines intersect with gate regions of the plurality of channels. In addition, arrays include a p-doped bridge extending between a first channel of the plurality of channels and a second channel of the plurality of channels, where the first channel is spaced apart from the second channel in a row extending in the second horizontal direction.

### CROSS REFERENCE TO RELATED APPLICATION

This application claims priority to U.S. Provisional Application No. 63/495,028 by Chen et al., entitled “4F2 DRAM WITH REDUCED FLOATING BODY EFFECT,” filed Apr. 7, 2023, and claims priority to U.S. Provisional Application No. 63/601,064 by Pesic et al., entitled “4F2 VERTICAL ACCESS TRANSISTOR WITH REDUCED FLOATING BODY EFFECT,” filed Nov. 20, 2023, the entire disclosure of which is hereby incorporated by reference, for all purposes, as if fully set forth herein.

### TECHNICAL FIELD

This disclosure generally describes designs for a 4F² vertical access transistor two-dimensional dynamic random access memory array. More specifically, this disclosure describes a 4F² memory array with decreased floating body effect.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (IT-1C) DRAM cell architecture has successfully scaled down from an 8F² size to a 6F² size (where F is the minimum feature size). Further design scheme changes from 6F² to 4F² may help further improve area density. In the 4F² DRAM scheme, storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. Therefore, improvements in the art are needed.

### BRIEF SUMMARY

Embodiments of the present technology are generally directed to vertical cell dynamic random-access memory (DRAM) arrays with improved hole distribution. The arrays include a plurality of bit lines arranged in a first horizontal direction. The arrays include a plurality of word lines arranged in a second horizontal direction. The arrays include a plurality of channels extending in a vertical direction orthogonal to the first direction and the second horizontal direction, such that the plurality of bit lines intersect with a source/drain region of the plurality of channels, and the plurality of word lines intersect with gate regions of the plurality of channels. Arrays include a p-doped bridge extending between a first channel of the plurality of channels and a second channel of the plurality of channels, where the first channel is spaced apart from the second channel in a row extending in the second horizontal direction.

In embodiments, the p-doped bridge has a doping level greater than or about 1.6 times a doping level of the first channel and the second channel. In more embodiments, the arrays further include a shallow trench isolation defined between the first channel and the second channel, where the shallow trench isolation has a height extending from a first end to a second end. In yet further embodiments, the p-doped bridge is disposed in the shallow trench isolation at about 20% to about 80% of the height of the shallow trench isolation. Additionally or alternatively, the array also includes at least a third channel of the plurality of channels spaced apart from the second channel in the row extending in the second horizontal direction, where a second p-doped bridge extends between the second channel and the third channel. In further embodiments, the arrays include a body contact in electrical connection with the p-doped bridge. Moreover, in embodiments, the body contact is connected to a biasing voltage source. In more embodiments, the arrays also include a bit line contact electrically connected to one or more of the plurality of bit lines, where the bit line contact is electrically isolated from the body contact. Further, in embodiments, devices include a second p-doped bridge extending between the first channel of the plurality of channels and the second channel of the plurality of channels.

Embodiments of the present technology are also generally directed to vertical cell random access memory (DRAM) arrays. Arrays include a plurality of bit lines arranged in a first horizontal direction. Arrays include a plurality of word lines arranged in a second horizontal direction. The arrays include a first plurality of spaced apart channels in a first row extending in the second direction. Arrays include a second plurality of spaced apart channels in a second row extending in the second horizontal direction, where the first row is spaced apart from the second row. Arrays include a plurality of p-doped bridges extending between adjacent channels in the first row and between adjacent channels in the second row. The arrays include where each of the channels extends in a vertical direction that is orthogonal to the first horizontal direction and the second horizontal direction such that the plurality of bit lines intersect with a source/drain region of the plurality of channels and the plurality of word lines intersect with gate regions of the plurality of channels.

In embodiments, arrays also include a shallow trench isolation defined between adjacent channels in each row, the shallow trench isolation having a height extending from a first end to a second end. In more embodiments, arrays also include a second shallow trench isolation between adjacent channels in the first row and the second row, and a gate formed alone an exterior surface of the second shallow trench isolation. In further embodiments, the arrays include a conductive material overlying each p-doped bridge. Additionally or alternatively, in embodiments, arrays include at least one body contact in each row, each of the at least one body contact extending from the first end of the shallow trench isolation to the doped material in the respective shallow trench isolation.

The present technology also includes methods of forming a vertical cell dynamic random-access memory (DRAM) array. Methods include etching a substrate to form a plurality of shallow trench isolations and a plurality of vertically extending channels having a first source/drain region at a second end of the vertically extending channels. Methods include forming a dielectric in one or more of the shallow trench isolations. Methods include recessing the dielectric to a height in the one or more shallow trench isolations. The methods also include forming a protective liner in the one or more shallow trench isolations and bottom punching the bottom surface of the protective liner. Methods include recessing the dielectric to a second height in the one or more shallow trench isolations below the first height. Methods include forming a p-doped bridge in the one or more shallow trench isolations, where the p-doped bridge contacts the first sidewall and the second sidewall of the one or more shallow trench isolations exposed by the recessing to the second height.

Embodiments also include filling a dielectric material into the one or more shallow trench isolations above the p-doped bridge. In more embodiments, methods include forming a conductive material over the p-doped bridge. Furthermore, in embodiments, methods include forming the p-doped bridge epitaxially and depositing the conductive material over the p-doped bridge. In embodiments, methods include etching an aperture in at least a portion of the one or more shallow trench isolations from an exposed surface of the vertical cell dynamic random access memory array to the conductive material in the one or more shallow trench isolations. Embodiments include metallizing a top surface of the conductive material and forming a conductive metal shield in the aperture and over an exposed surface of the vertical cell dynamic random access memory array. In embodiments, methods include forming an interlayer dielectric over the conductive metal shield and etching a second aperture through the interlayer dielectric to a bit line formed over a second source/drain region formed at a first end of the vertically extending channels, and isolating the aperture from the conductive metal shield.

Such technology may provide numerous benefits over conventional systems and techniques. For example, the processes and systems may distribute holes across multiple channels, reducing hole accumulation effects. Additionally, the processes and systems may significantly reduce hole accumulation in the body of a 4F² DRAM device. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a semiconductor structure according to embodiments of the present technology with a dielectric material fill after first shallow trench isolation formation.

FIG. 3B shows a perspective view of a semiconductor structure according to embodiments of the present technology with a recessed dielectric material.

FIG. 3C shows a perspective view of a semiconductor structure according to embodiments of the present technology with a protective liner.

FIG. 3D shows a perspective view of a semiconductor structure according to embodiments of the present technology with the protective liner bottom removed.

FIG. 3E shows a perspective view of a semiconductor structure according to embodiments of the present technology with the dielectric material etched back.

FIG. 3F shows a perspective view of a semiconductor structure according to embodiments of the present technology where the exposed substrate has been cleaned.

FIG. 3G shows a perspective view of a semiconductor structure according to embodiments of the present technology with bridges formed between adjacent channels.

FIG. 3H shows a perspective view of a semiconductor structure according to embodiments of the present technology with a fill formed over the bridges.

FIG. 4 shows selected operations in a formation method according to embodiments of the present technology.

FIG. 5A shows a perspective view of a semiconductor structure according to embodiments of the present technology with a conductive material formed over the bridges.

FIG. 5B shows a perspective view of a semiconductor structure according to embodiments of the present technology with the conductive material etched back.

FIG. 5C shows a perspective view of a semiconductor structure according to embodiments of the present technology with a dielectric material filled over the conductive material.

FIG. 5D shows a perspective view of a semiconductor structure according to embodiments of the present technology with shallow trench isolations formed in the word line direction.

FIG. 5E shows a perspective view of a semiconductor structure according to embodiments of the present technology with bridge contact apertures.

FIG. 5F shows a perspective view of a semiconductor structure according to embodiments of the present technology with bridge metallization contacts.

FIG. 5G shows a perspective view of a semiconductor structure according to embodiments of the present technology with a body contact.

FIG. 5H shows a perspective view of a semiconductor structure according to embodiments of the present technology with an insulated bit line contact trench.

FIG. 5I shows a perspective view of a semiconductor structure according to embodiments of the present technology with an insulated bit line contact.

FIG. 6A shows a perspective view of a semiconductor structure according to embodiments of the present technology with a first bridge formed.

FIG. 6B shows a perspective view of a semiconductor structure according to embodiments of the present technology with a doped layer formed over the first bridge.

FIG. 6C shows a perspective view of a semiconductor structure according to embodiments of the present technology with a second bridge formed above the first bridge.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, the 4F² DRAM design comes with its own challenges. For example, 4F² memory cells have the transistor channel disposed between the bitline and the capacitor layers, leaving no common substrate connecting the channels, resulting in a floating body effect for these transistors. For instance, it is believed that conventional 4F² DRAM access devices exhibit off-leakage current issues. Off-leakage current results from the floating body effect, such as hole accumulation in the body of a 4F² DRAM device due to the isolated channels. Electron-hole pairs can form in a semiconductor channels due to band-to-band tunneling, causing gate induced drain leakage (GIDL). While the electrons can flow into the n-type source or drain regions of the transistor, the holes cannot. For 4F² DRAM devices without a substrate connection, the holes have no path to leave the channel and will continue to accumulate. Thus, the floating body effect may lead to channel activation without gate activation, which eventually translates into leakage current from the capacitor, or data storage side of the device, as well as into degradation of the threshold voltage over time.

Attempts have been made to provide body connections utilizing a buried body contact scheme. However, such attempts can result in gate overlap to a source/drain junction edge, allowing undesired gate-induced drain leakage, or limited scalability to small dimensions. Moreover, such design schemes are also capable of producing high aspect ratio structures that challenge existing doping techniques.

The present technology overcomes these and other problems by connecting two or more channels of a vertically arranged transistor in a respective row of cells with one or more p-type bridges outside of the source/drain region of the transistor. Namely, one or more p-type bridges between channels (e.g. extending along the gate, or word-line direction), provides a pathway for hole movement between channels when the gate is off, reducing gate induced leakage current and/or the floating body effects impact on the channel. In addition, with a doping level sufficient to prevent noticeable electron sharing between channels, when the channels along the word-line are biased on, the transistor on-current is not impacted, and electrons continue to flow from source to drain. Thus, the present technology provides for reduction in the floating body effect without disrupting the size or connections of the 4F² DRAM device. Moreover, in embodiments, one or more bridges between adjacent channels in a respective row can also serve as a connection point for a body contact. Thus, in embodiments, the present technology provides for adjacent channels to be connected together locally to provide a common floating body, or even be biased to a desired body potential. Namely, by utilizing one or more body contacts, the floating body effect can be reduced or even eliminated without introducing undesired gate overlap near the source/drain junction edges.

Although the remaining disclosure will routinely identify specific deposition and etch processes utilized for forming vertical cell dynamic random access memory (DRAM) arrays, such as a 4F² DRAM device, it will be readily understood that the systems and methods are equally applicable to other DRAM devices, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components, utilizing one or more bridges according to embodiments of the present technology before additional variations and adjustments to this apparatus according to embodiments of the present technology are described.

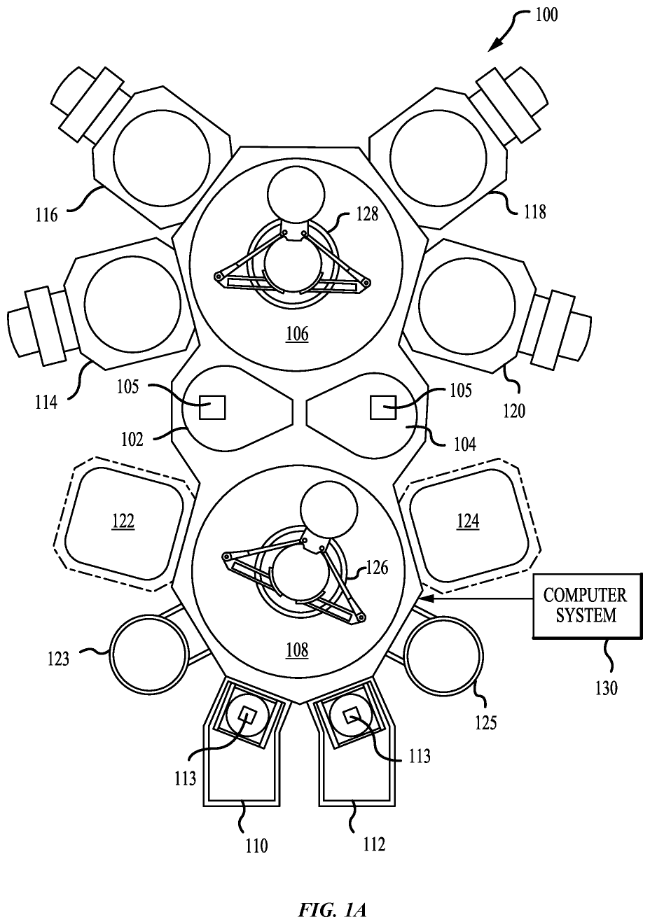

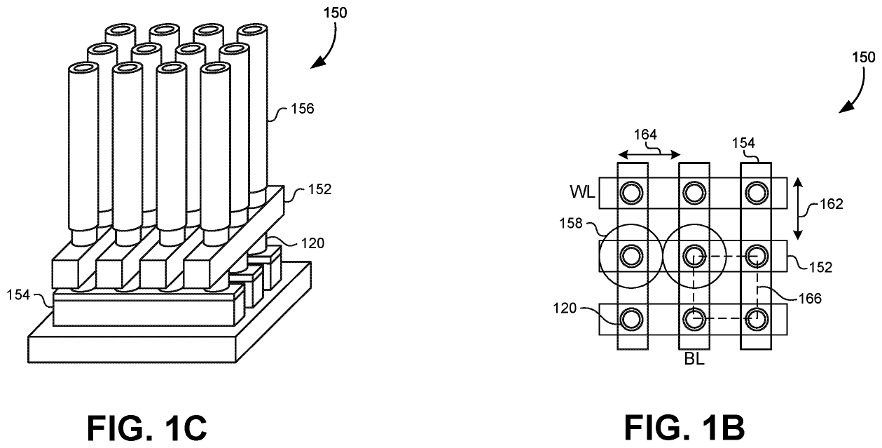

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

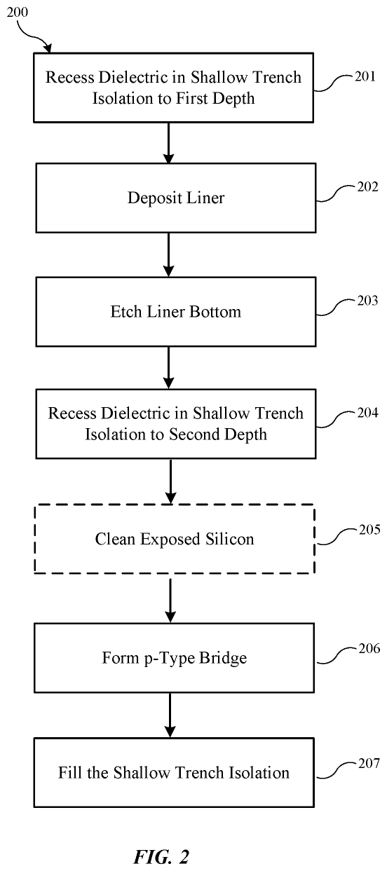

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically from the word line side of the structure to the bit line side of the structure, it should be understood that the other orientation from bit line to word line side may be utilized.

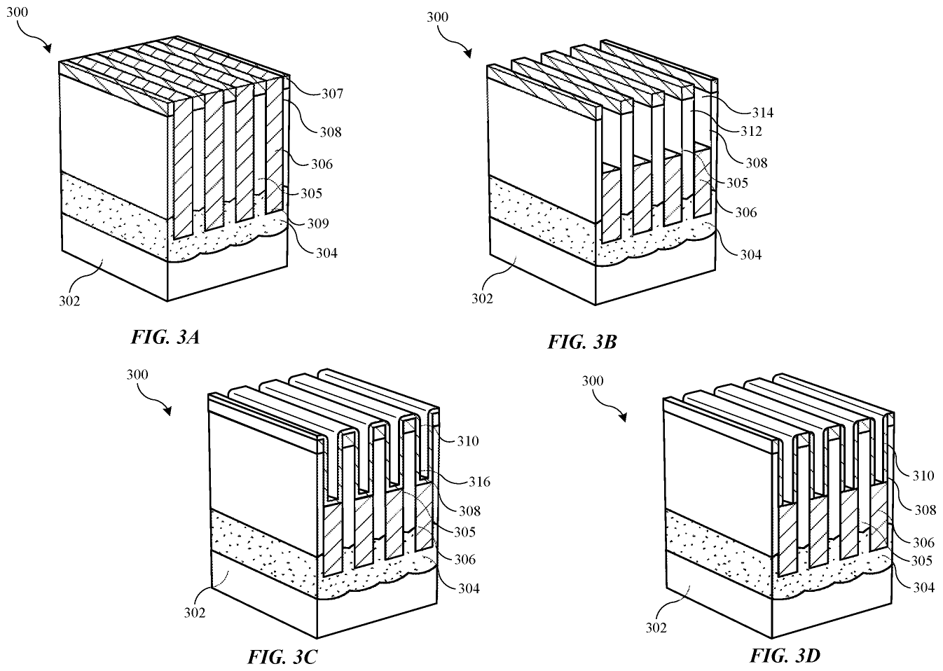

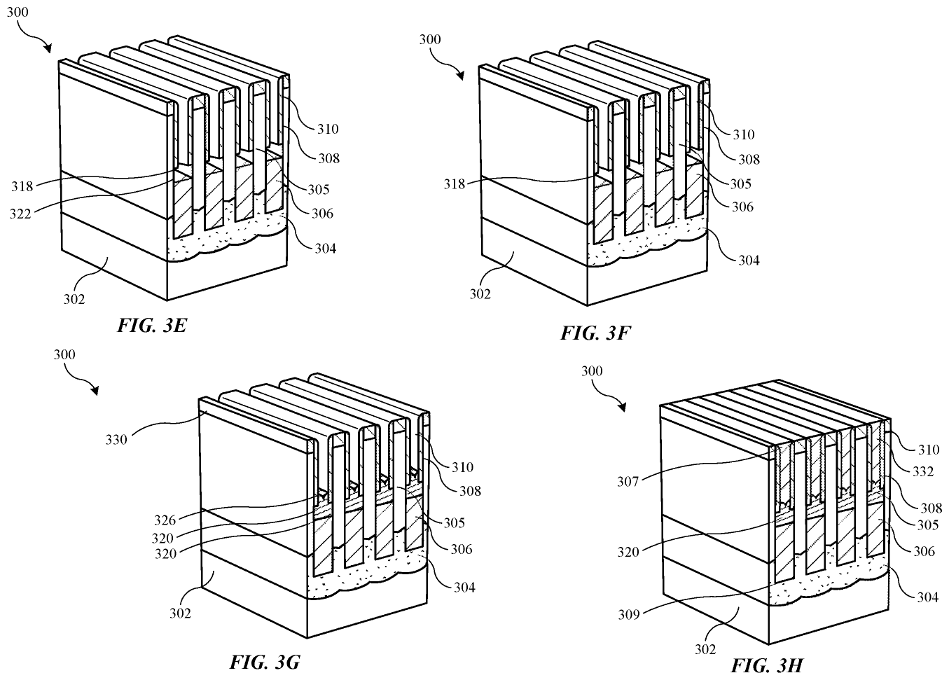

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in FIGS. 3A-3H, the illustrations of which will be described in conjunction with the operations of method 200. It is to be understood that FIG. 3A-3H illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in FIG. 3A-3H, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

In embodiments, the structure 300 may include a semiconductor substrate 302, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that includes a substrate 302 that has already undergone source/drain 304 formation, shallow trench isolation formation 308, and first dielectric material 306 fill in shallow trench isolations 308. In addition, two or more walls 305 are formed between respective shallow trench isolations 308, where the illustrated walls 305 are spaced apart in a horizontally extending row parallel to a word line direction in this embodiment. In embodiments, source/drain 304 formation may include one or more ion implants followed by a subsequent anneal activation process. The implant process may be a single implant or may include a series of multiple implants. When multiple implants are utilized, each implant may utilize the same ion, or different ions. Although, it should be understood that the source/drain region 304 may be formed from any suitable process. The method may include providing a semiconductor structure having first source/drain regions 304 for a plurality of vertical channels, and forming a plurality of word lines that contact the first source/drain regions. Overall, this process may incrementally form each stage of the transistor on top of a previous completed stage.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

Nonetheless, at operation 201, method 200 may include recessing the first dielectric material 306 to a first recessed height in one or more of the shallow trench isolations 308 as illustrated in FIG. 3B. For instance, in embodiments, a substrate 302 may be loaded into load lock 110, 112, and transferred to a process chamber (such as process chamber 114) via robots 126, 128, where first dielectric material 306 is recessed. It should be understood that the substrate may be transferred between each operation step, or only a portion of the operation steps, as some operation steps may be completed in the same processing chamber. In embodiments, the dielectric material may be recessed to an approximate midpoint of the respective shallow trench isolation 308. However, it should be understood that the first dielectric material 306 may be recessed to a height that is about 20% to about 80% of the height of each respective shallow trench isolation 308, such as from about 30% to about 70%, such as from about 40% to about 60%, such as from about 45% to about 55%, or any ranges or values therebetween. Namely, each shallow trench isolation 308 defined between adjacent channels has a first end 307 and a second end (shown more clearly in FIG. 3H), and defines a trench height therebetween. However, as discussed in greater detail below, a greater recess height may be utilized in embodiments that include more than one p-type bridge. Moreover, recessing operation 201 may be conducted by any method as known in the art.

As illustrated in FIG. 3C, after recessing operation 201, a protective liner 310 may be formed over recessed first dielectric material 306 and an exposed portion of the first sidewall 312 and the second sidewall 314 (shown more clearly in FIG. 3B) of each shallow trench isolation 308 at operation 202. The protective liner 310 may be formed from any dielectric material having a different etch rate than first dielectric material 306 as known in the art, such as a silicon nitride, a silicon oxynitride, silicon dioxide, or other similar materials. Additionally or alternatively, in embodiments, the protective liner 310 may be formed from the same material as first dielectric material 306, but has a thickness so as to retain at least a portion of the protective liner 310 after the second recessing operation 204. Nonetheless, as illustrated in FIG. 3D, after formation of the protective liner 310, the protective liner 310 bottom 316 may be etched out at operation 203 to expose first dielectric material 306. Such an etching process that selective removes the bottom surface may be referred to as a “bottom punch”, also referred to as an anisotropic or directional etch. In embodiments, the selective bottom etching or bottom punching may be performed by any etch processes as known in the art, such as reactive ion etch.

Nonetheless, after bottom etching the protective liner 310, the first dielectric material 306 may undergo a second recessing step at operation 204, as illustrated in FIG. 3E. The recessing operation 204 may be selective for first dielectric material 306, without removing protective liner 310 from first sidewall 312 and second sidewall 314 of shallow trench isolation 308. Namely, at least a portion of protective liner 310 remains on the first sidewall 312 and second sidewall 314. Regardless, first dielectric material 306 is etched from the first height to a second height below the first height. By etching the first dielectric material 306 to a second height, an exposed portion 322 of the first sidewall 312 and the opposed second sidewall 314 is formed between the first dielectric material 306 at the second height and a bottom surface 318 of protective liner 310. In embodiments, the second height is a distance below the first height so as to provide a robust contact area for bridge 320.

Thus, in embodiments, the height difference from the first height to the second height, and/or the length of the exposed portion of first sidewall 312 and second sidewall 314 may be greater than or about 2 nm, such as greater than or about 4 nm, such as greater than or about 6 nm, such as greater than or about 8 nm, such as greater than or about 10 nm, such as greater than or about 12 nm, such as greater than or about 14 nm, such as greater than or about 16 nm, such as greater than or about 18 nm, such as greater than or about 20 nm, such as less than or about 50 nm, such as less than or about 45 nm, such as less than or about 40 nm, such as less than or about 35 nm, such as less than or about 30 nm, such as less than or about 25 nm, or any ranges or values therebetween. Namely, in embodiments, the distance and/or length may be selected so as to provide enough contact area for a robust electrical connection, without being so large that the bridge 320 impacts the overall doping level of the respective wall 305.

Notwithstanding the height the dielectric material is etched to, the exposed portion 322 of first sidewall 312 and opposed second sidewall 314 is optionally cleaned at operation 205. The optional cleaning operation 205 may include a preclean operation and/or a surface damage removal operation. Namely, in order to effectively distribute holes between channels, each bridge 320 must have a robust electrical connection with each of the adjacent walls 305. However, surface oxidation, damaged silicon from recessing operation 204, and other contaminants can prevent efficient merging of bridge 320 with first sidewall 312 and/or second sidewall 314. Thus, in embodiments, operation 205 includes selectively removing surface damage (e.g. silicon damaged during recessing operations, if any) from the exposed portion 322 of first sidewall 312 and second sidewall, such as with an isotropic etch process, as illustrated in FIG. 3F. An isotropic etch process, such as a gas-phase etch, is available from Applied Materials (Selectra™) which removes doped and undoped silicon while retaining dielectric materials. In embodiments, only one or more layers forming or adjacent to exposed surface 322 is/are removed. In embodiments, a preclean, such as a Siconi™ clean may remove any surface oxides present. However, in embodiments, cleaning may not be necessary. Namely, in embodiments, method 200 may be conducted completely within processing system 100 without removal from vacuum, limiting the formation of oxides and other surface defects after oxide removal by recessing operation 204. Additionally or alternatively, no damaged silicon may be present after recessing operation 204. Thus, in embodiments, both a preclean and a surface damage removal operation may be utilized, only one of a preclean and a surface damage removal operation may be utilized, or neither a preclean or a surface damage removal operation may be utilized.

Method 200 further includes forming a p-doped bridge 320 between two adjacent walls 305 that extend along a single row (e.g. the bridge 320 is formed along or parallel to the gate, which will be discussed in greater detail below) at operation 206, as illustrated in FIG. 3G. In embodiments, the p-doped bridge 320 may be formed from the same material as the two or more walls 305, or a different material suitable for forming a p-doped bridge between adjacent walls 305, such as any substrate material or another material. However, in embodiments, p-doped bridge 320 has a higher doping level than the walls 305 adjacent to the respective bridge 320. Namely, by utilizing a doping level higher than the walls 305 adjacent to the respective bridge, charge sharing between walls 305 via bridge 320 may be minimal or nonexistent when the walls 305 are biased on, as the voltage threshold is below the activation threshold of bridge 320. Nonetheless, the doping level must also not be significantly above the doping level of the two or more walls 305, as the dopant may diffuse into the two or more walls 305, raising the threshold of the channel above the bias voltage.

Thus, in embodiments, each of the bridges 320 may have a doping level that is greater than or about 1.6 times a doping level of the walls 305 adjacent to the respective bridge 320, such as greater than or about 1.8 times, such as greater than or about 2 times, such as greater than or about 2.2 times, such as greater than or about 2.4 times, such as greater than or about 2.6 times, such as greater than or about 2.8 times, such as greater than or about 3 times, such as less than or about 5 times, such as less than or about 4.8 times, such as less than or about 4.6 times, such as less than or about 4.4 times, such as less than or about 4.2 times, such as less than or about 4 times, such as less than or about 3.8 times, such as less than or about 3.6 times, such as less than or about 3.4 times, or any ranges or values therebetween.

Stated differently, in embodiments, the doping concentration of the one or more p-doped bridges 320 may be greater than or about 5×10¹⁶ cm⁻³, such as greater than or about 6×10¹⁶ cm⁻³, such as greater than or about 7×10¹⁶ cm⁻³, such as greater than or about 8×10¹⁶ cm⁻³, such as greater than or about 9×10¹⁶ cm⁻³, such as greater than or about 1×10¹⁷ cm⁻³, such as greater than or about 2×10¹⁷ cm⁻³, such as greater than or about 4×10¹⁷ cm⁻³, such as greater than or about 6×10¹⁷ cm⁻³, such as greater than or about 8×10¹⁷ cm⁻³, such as greater than or about 1×10¹⁸ cm⁻³, such as greater than or about 2×10¹⁸ cm⁻³, such as greater than or about 4×10¹⁸ cm⁻³, such as greater than or about 6×10¹⁸ cm⁻³, such as greater than or about 8×10¹⁸ cm⁻³, such as greater than or about 1×10¹⁹ cm⁻³, such as greater than or about 2×10¹⁹ cm⁻³, such as greater than or about 1×10²⁰ cm⁻³, such as greater than or about 2×10²⁰ cm⁻³, such as greater than or about 5×10²⁰ cm⁻³, or such as less than or about 1×10²² cm⁻³, such as less than or about 1×10²¹ cm⁻³, or any ranges or values therebetween.

Namely, as discussed above, each bridge 320 may have a sufficient doping level to prevent significant charge sharing, e.g., a level of doping sufficient to provide a Vt above a gate threshold for the walls 305 adjacent to the respective bridge. Nonetheless, as each bridge 320 has a higher level of dopant than the adjacent walls 305, each bridge 320 may diffuse dopant from the center of the respective bridge 320, towards and into the adjacent walls 305. The diffusion may therefore form a gradient of dopant from wall 305 towards the center of each bridge 320. Such a phenomena may improve hole attraction, reducing the floating body effect, as holes may move from problematic areas of one or more walls 305 into respective bridge 320, where the holes may be distributed across the bridge 320, or move fully along bridged rows between connected bridges 320 and walls 305, distributing the holes along a large area and dissipating the effects. However, if the doping level is too high in the one or more bridges 320 compared to adjacent walls 305, diffusion of dopant may increase the doping level of the one or more walls 305 to a level above a threshold value for the wall 305. Therefore, in embodiments, the doping level of each bridge compared to the adjacent walls 305 is carefully selected. Regardless, the present technology has surprisingly found that bridges 320 drastically reduce the floating body effect, such as by reducing channel potential increases and reducing off-leakage current.

Nonetheless, in embodiments, a number of different materials may be used for the one or more bridges 320. For example, the one or more bridges may include a crystalline semiconductor, such as silicon, germanium, silicon germanium, and/or other similar materials. In embodiments, the bridges may be formed from a crystalline silicon, such as a single crystalline silicon in embodiments, or any one or more of the semiconductor materials discussed above. These materials may also be used in a polycrystalline semiconductor form. In embodiments, the one or more bridges 320 may be formed by epitaxially growing epitaxial silicon on recessed first dielectric material 306 in shallow trench isolation 308, and merging the epitaxial layer until good contact with both the first sidewall 312 and second sidewall 314 is achieved. Thus, in embodiments, such a processes may be referred to as a selective epi-deposition process.

Alternatively, the one or more bridges 320 may be formed by conformally filling the shallow trench isolation 308 with one or more polycrystalline semiconductor layers, or by depositing one or more polycrystalline semiconductor layers utilizing other deposition methods known in the art. Regardless of the method used, it should be clear that the material used for the one or more bridges 320 is deposited or grown so as to provide good electoral contact with the exposed portion 322 of both the first sidewall 312 and second sidewall 314. However, in embodiments, the one or more bridges 320 may not fully merge with or contact first dielectric material 306, so long as a strong electrical hole contact is formed with first sidewall 312 and second sidewall 314.

Furthermore, in embodiments, a metal oxide may be utilized as one or more bridges 320. In such embodiments, the metal oxide may be physically connected to the adjacent channels but not in electrical connection. In such a manner, holes may still be attracted to the metal oxide without an electrical connection to the adjacent channels.

In embodiments, the one or more bridges 320 are only formed in a portion of shallow trench isolation 308. For instance, as illustrated in FIG. 3G, the one or more bridges 320 have a height slightly greater than a height of the exposed portion 322, and may therefore extend into protective liner 310. However, in embodiments, the one or more bridges 320 may have a height that is generally the same as the height of exposed portion 322. Namely, while the shallow trench isolation 308 may be fully filled with bridge 320 material above first dielectric material 306, such an embodiment may allow for undesired high electric fields at upper regions of the shallow trench isolation 308, such as within source/drain regions if protective liner 310 is not fully or evenly formed.

Thus, in embodiments, the thickness (measured from bridge bottom 324 to bridge top 326) of the one or more bridges 320 may be greater than or about 2 nm, such as greater than or about 4 nm, such as greater than or about 6 nm, such as greater than or about 8 nm, such as greater than or about 10 nm, such as greater than or about 12 nm, such as greater than or about 14 nm, such as greater than or about 16 nm, such as greater than or about 18 nm, such as greater than or about 20 nm, such as greater than or about 25 nm, such as greater than or about 30 nm, such as less than or about 70 nm, such as less than or about 60 nm, such as less than or about 50 nm, such as less than or about 40 nm, such as less than or about 35 nm, or any ranges or values therebetween. Namely, in embodiments, the thickness may be selected so as to provide enough contact area for a robust connection. However, as will be discussed in greater detail below, in embodiments, such as when two or more bridges are utilized, it may not be necessary to form a direct connection between one or more bridges and adjacent walls. In such an embodiment, the cleaning and/or recessing operations 204 and/or 205 may be omitted. Namely, without wishing to be bound by theory, the doping may be sufficiently tuned such that adequate hole distribution is achieved without a direct connection between the bridge and one or more channel walls.

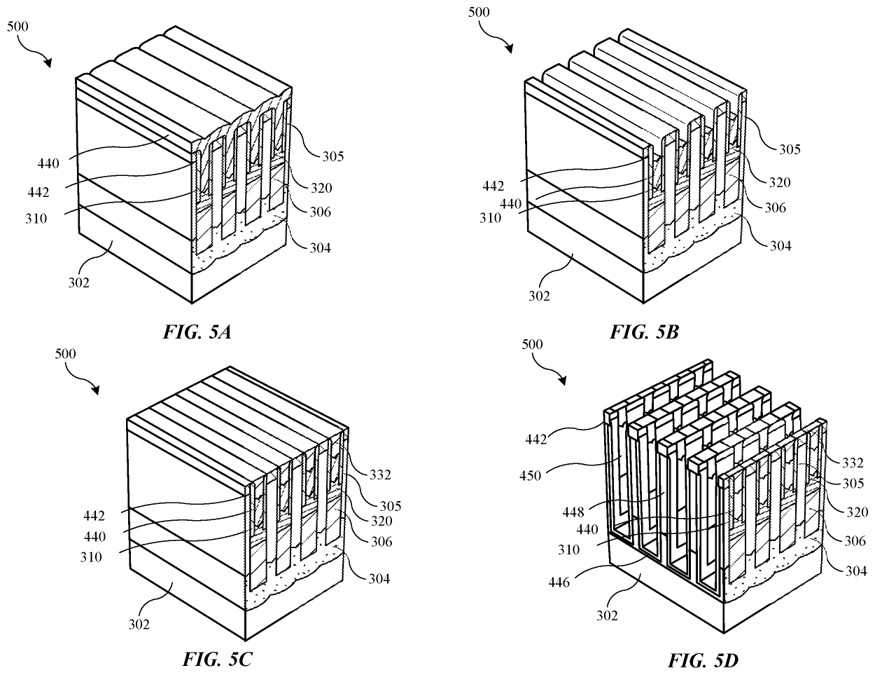

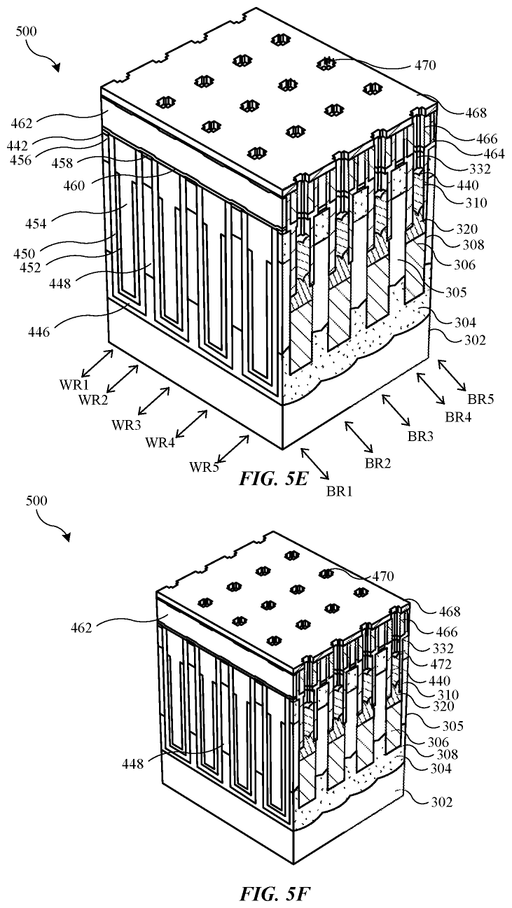

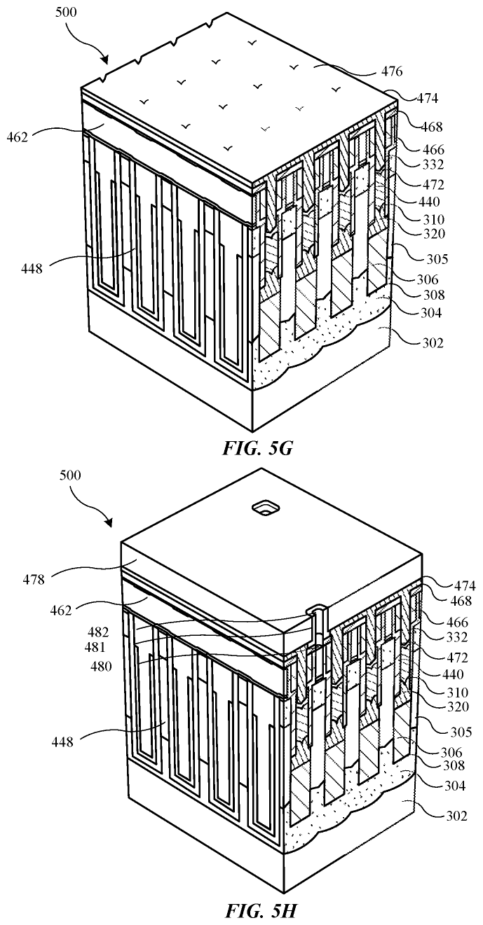

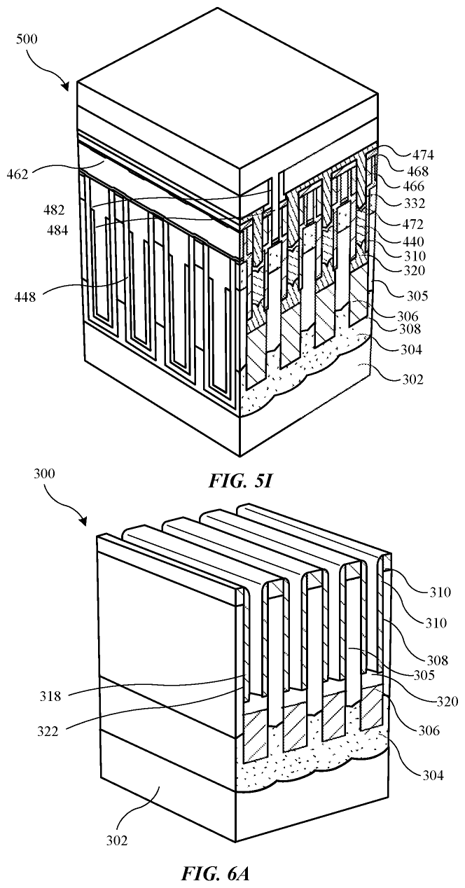

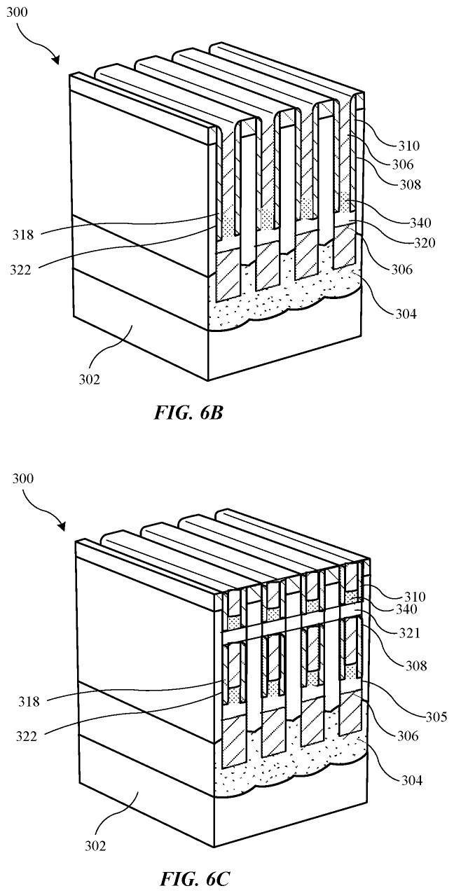

In addition, as discussed above, in embodiments, the one or more bridges are formed at approximately a center point of the two or more walls 305 (and therefore shallow trench isolation 308). Namely, by utilizing a bridge at an approximate center point of the two or more walls 305, holes may be distributed among adjacent channels. However, it should be understood that in embodiments, more than one bridge 320 may be utilized between two respective walls 305, and neither or one of such bridges 320 may not be located at approximately a center point, as will be discussed in greater detail below in regards to FIGS. 6A-6C. For instance, as a first bridge 320 disposed adjacent to a source/drain region 304 and a second bridge 320 formed adjacent to a second source drain region (shown more clearly in FIGS. 5A-5I) of semiconductor structure 300. Nonetheless, regardless of the number of bridges utilized between two respective channels, at least one of the bridges 320 may be formed in shallow trench isolation 308 at a height of about 20% to about 80% of the height of each respective shallow trench isolation 308, such as from about 30% to about 70%, such as from about 40% to about 60%, such as from about 45% to about 55%, or any ranges or values therebetween.

After formation of the p-type bridge at operation 206, the remainder of the shallow trench isolation 308 above bridge 320 may be filled at operation 207. FIG. 3H illustrates the fill being conducted with a second dielectric material 332, which may be the same dielectric material as first dielectric material 306 or a different dielectric material than initially filled in shallow trench isolation 308 in FIG. 3A. In embodiments, the first and/or second dielectric material 332 may be any one or more dielectric material(s), such as a silicon oxide, silicon oxycarbide, silicon oxynitride, silicon oxycarbonitride, combinations thereof, or other dielectric material as known in the art, formed utilizing any fill methods discussed above and as known in the art. Although the following description will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed Nonetheless, as will be discussed in greater detail below, it should be understood that other materials may be utilized at operation 207.

In embodiments, after fill operation 207, the semiconductor structure 300 may re-enter a normal process flow for a vertical cell DRAM array, such as a 4F² DRAM array, and undergo one or more further processing steps. For instance, the semiconductor structure 300 may be planarized, such as by utilizing polishing. Moreover, the semiconductor structure may undergo one or more additional masking, etching, deposition, and/or filling steps to form the second set of rows orthogonal to the rows of channels discussed above, as well as formation of the bit lines and second source/drain regions, which may be discussed in greater detail below. However, as will be discussed in greater detail below, in embodiments where more than one p-type bridge is utilized, operations 204-207 may be repeated as necessary to form the additional p-type bridges.

Nonetheless, in embodiments, it may be beneficial to further reduce or even eliminate the floating body effect in a vertical cell DRAM array, such as a 4F² DRAM array. Thus, in embodiments, operation 207 may include filling shallow trench isolation 308 above bridge 320 with one or more conductive materials 440 as illustrated in FIG. 5A (e.g., operation 206 as illustrated in FIG. 3G followed by operation 207 illustrated in FIG. 5A). In embodiments, filling with a conductive material, which may be a doped material, such as the same material as bridge 320, or any other conductive material as known in the art, may occur by epitaxially growing a conductive material, such as crystalline silicon in embodiments, on bridge 320 in shallow trench isolation 308. Alternatively, the fill over the one or more bridges 320 may be formed by conformally filling the shallow trench isolation 308 with one or more conductive materials, or by depositing one or more conductive material layers utilizing other deposition methods known in the art. Nonetheless, in embodiments, it should be understood that operation 207 may be optional, as the bridge 320 itself may be extended to a top surface 330 of the semiconductor structure instead of utilizing an additional fill step. Regardless of the formation method, the present technology has surprisingly found that the formation of bridge 320 and conductive material 440 may be conducted in the same chamber, such as one of processing chambers 114, 116, 118, 120, 122, and 124 discussed above. Thus, in embodiments, the epitaxial growing process and/or the filling process of bridge 320 may be conducted in the same processing chamber as the epitaxial growing process and/or filling process of conductive material 440.

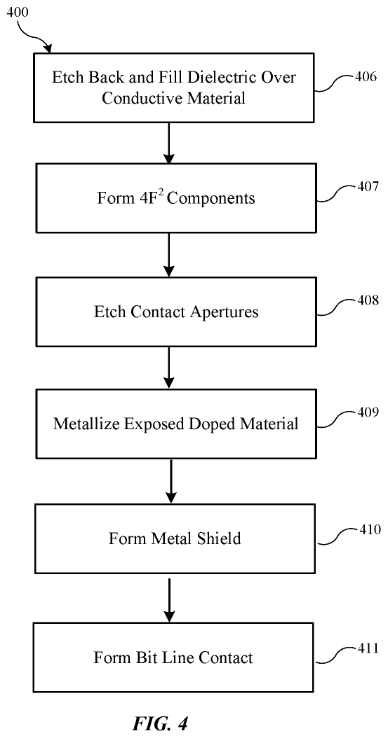

For instance, FIG. 4 shows exemplary operations in a method 400 according to some embodiments of the present technology. The method may be performed in a variety of processing chambers, including processing chamber 100 described above. Method 400 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 400 describes operations shown schematically in FIGS. 5A-5I, the illustrations of which will be described in conjunction with the operations of method 400. It is to be understood that FIG. 5A-5I illustrate only partial schematic views, and a semiconductor substrate may include further components as illustrated in the figures, as well as alternative components, of any size or configuration that may still benefit from aspects of the present technology.

For instance, as discussed above, in embodiments, operation 207 may include filling a conductive material that is different from bridge 320 material, over bridge 320, or may include filling the shallow trench isolation 308 with bridge 320 material. However, it should be understood that, in embodiments, “different” may include polycrystalline versions of a single crystalline material and vice versa (e.g. a bridge 320 formed from crystalline silicon and a doped material layer formed from polycrystalline silicon). Nonetheless, operation 406 includes etching back the conductive material 440 illustrated in FIG. 5B and filling the shallow trench isolation 308 with second dielectric material 332 over conductive material 440 in FIG. 5C. The etch back of conductive material 440 may be conducted by any methods discussed above, or as known in the art. However, in embodiments, the conductive material 440 is etched to a height below a top surface 442 of wall 305. Namely, as discussed above, in embodiments, conductive material 440 (and/or bridge 320 material) may interact with wall 305 through any gaps or holes in protective liner 310, where defects are more likely to occur at a top surface 442 of wall 305. Thus, in embodiments, to reduce the likelihood of a short between wall 305 and conductive material 440/bridge 320 material, the conductive material 440/bridge 320 material is etched back to a height below a top surface 442 of wall 305.

Thus, FIG. 5C illustrates the fill of operation 406 being conducted with second dielectric material 332, which may be the same dielectric material as first dielectric material 306 or a different dielectric material than initially contained in shallow trench isolation 308 in FIG. 3A. In embodiments, the second dielectric material 332 may be any one or more dielectric material(s), such as silicon oxide, formed utilizing any fill methods discussed above and as known in the art. As illustrated, the semiconductor structure 500 may also undergo planarization, such as polishing, after etch back and re-fill operation 406.

Next, operation 407 includes a standard process flow for 4F² DRAM arrays utilizing any methods and techniques as known in the art.

For instance, FIG. 5D illustrates etching of shallow trench isolations 446 extending in a second horizontal direction, forming channels 448, and the deposition of a third dielectric material 450. Namely, as discussed above for the formation of shallow trench isolations 308 between walls 305, a pattern or mask defining second shallow trench isolations 446 may be used to form the isolations between channels 448, which run in a row parallel or in plane with word lines in this embodiment, formed by an etch process. The resulting channels 448 may have a uniform or nonuniform width, and/or a width generally equal to walls 305. The second shallow trench isolations 446 may serve to isolate neighboring channels 448.

Moreover, FIG. 5D illustrates the formation of a third dielectric material 450 along adjacent walls 305 and bridges 320 in rows extending in the first horizontal direction (e.g. such that third dielectric material 450 is generally parallel with the word line direction). The third dielectric material 450 may be formed from materials such as SiO₂ or other similar materials. For example, SiO may be oxidized from the walls 305 and/or 448 to be used as the dielectric material 450, or may be deposited as known in the art. Notwithstanding the method, the third dielectric material extends generally alone an external perimeter of the respective shallow trench isolation 446. The thickness of the dielectric material may be between about 1 nm and about 10 nm.

FIG. 5E illustrates a semiconductor structure 500 having a variety of a vertical cell DRAM array, such as a 4F² DRAM array, components formed thereon. For instance, after the formation of third dielectric material 450, a gate metal 452 is formed on the third dielectric material 450 generally along an exterior perimeter of shallow trench isolation 446. In embodiments, the gate metal may be a low-resistance metal, such as tungsten, titanium nitride, titanium, ruthenium, cobalt, molybdenum, the like, or combinations thereof. As illustrated, in embodiments, the gate metal 452 may be etched back below a second source/drain region 456 of the first walls 305 and/or channels 448.

A spacer 454 has been formed in second shallow trench isolations 446 between adjacent channels 448. The spacer layer(s) 454 may be formed from any insulating material, such as SiO, SiN, dielectrics, or other similar materials. In embodiments, the spacer layer(s) 454 may be filled utilizing any method known in the art, and then etched back. For instance, in embodiments, the spacer layer 454 may be filled and etched back to a level below a second source/drain region 456 of the first walls 305 and/or channels 448 to provide for recessing of the gate metal 452, followed by a second fill of the same or different insulating material. In some embodiments, a planarization process may be performed to create a flat surface at the top of the stack for the formation of subsequent layers.

For instance, as shown, a portion of the walls 305 and/or 448 have been subjected to source/drain formation, forming second source/drain regions 456 adjacent to a top 442 of the respective channels. As discussed above with source/drain regions 304, in embodiments, second source/drain 456 formation may include one or more ion implants followed by a subsequent anneal process. The implant process may be a single implant, or may include a series of multiple implants. When multiple implants are utilized, each implant may utilize the same ion, or different ions. Although, it should be understood that the second source/drain regions 456 may be formed from any suitable process.

In addition, the second source/drain regions 456 may undergo a metallization process, such as silicidation to form a cap 458. For instance, a metal layer may be applied over second source/drain regions 456 and exposed to a silicidation process. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting cap 458 may be a metallized layer of any one or more of the above metals and the channel material, such as silicon. In such an example only, the cap 458 layer may be a titanium silicide molybdenum silicide, or a combination thereof.

Nonetheless, a barrier layer 460 and one or more layers of bit line 462 material may be formed over a full exposed top surface (e.g. surface of the semiconductor structure 500 planar with top surface 442, serving as the top or exposed surface at this process step). The barrier layer 460 and bit line layer 462 may then be etched during bit line formation to remove barrier layer 460 material and bit line layer 463 material over shallow trench isolations 308, while leaving enough material to overlie and connect respective caps 458, third dielectric material 450, and spacer layer(s) 454 of walls 305.

In embodiments, barrier layer 460 may be a nitride, oxynitride, carbonitride, and/or oxycarbonitride of cobalt (Co), copper (Cu), nickel (Ni), ruthenium (Ru), manganese (Mn), silver (Ag), gold (Au), platinum (Pt), iron (Fe), molybdenum (Mo), rhodium (Rh), titanium (Ti), tantalum (Ta), silicon (Si), tungsten (W), or combinations thereof. Moreover, bit lines 462 may be a material deposited by any suitable technique known in the art, such as one or more deposition or filing techniques discussed above. In some embodiments, the bit line(s) 462 includes one or more of tungsten (W), ruthenium (Ru), iridium (Ir), platinum (Pt), rhodium (Rh) or molybdenum (Mo). In embodiments, the bit line 462 material is one or more of ruthenium or tungsten.

As illustrated, a spacer 464 may be included along each bit line layer 462. The spacer 464 may be the same material as protective liner 310. However, in embodiments, spacer 464 may be any of the insulative materials discussed in regards to spacers 454, and applied according to any of the methods discussed, regardless of the material of protective liner 310. In embodiments, spacer 464 may be applied as a conformal layer over the exposed surface of the semiconductor structure 500. In addition, a further dielectric material 466 may be filled between spacers 464. Further dielectric material 466 may be any one or more of the dielectric materials discussed above, and may be filled according to any of the techniques previously discussed.

Nonetheless, an interlayer dielectric 468 is formed over further dielectric material 466 and spacers 464, which may be planarized prior to formation. The interlayer dielectric 468 may be formed from any one or more of the above discussed dielectric materials utilizing any of the application techniques. For example only, the interlayer dielectric 468 may be referred to as silicon nitride.

Regardless of the material and method of formation of interlayer dielectric 468, one or more apertures 470 are etched through interlayer dielectric 468, dielectric material 466, spacer layer 464, and dielectric material 332 at operation 408, exposing conductive material 440 (and/or bridge 320 material if the bridge 320 material is extended during bridge formation operation 206 and/or re-fill operation 207 as discussed above). The apertures 470 may be aligned with and disposed vertically above one or more bridges 320. While one aperture 470 is shown for each bridge 320 (e.g. 12 bridges in this example), it should be understood that, due to the hole sharing nature of bridges 320 and walls 305 in a respective row, only one aperture per respective bridge connected wordline row (e.g. WR1, WR2, WR3, WR4, and WR5 in the illustrated embodiment, although more or less rows may be present) may be necessary.

Thus in embodiments, each respective bridge connected row includes at least one aperture. Additionally or alternatively, in embodiments, each bridge connected row may include a number of apertures less than or equal to the number of bridges 320, such as a number of apertures equal to less than or about 90% of the bridges, such as less than or about 80%, such as less than or about 70%, such as less than or about 60%, such as less than or about 50%, such as less than or about 40%, such as less than or about 30%, such as less than or about 20%, such as less than or about 10% of the bridges in a respective row, or any ranges therebetween, so long as each bridge connected row contains at least one aperture 470.

Moreover, in embodiments, when the number of apertures 470 is less than the number of bridges 320, the apertures may be aligned in a bit line row (e.g. BR1, BR2, BR3, BR4, or BR5), or may be in spaced apart in one or more of rows BR1-BR5 and WR1-WR5. For example only, a first aperture 470 may be disposed in WR5-BR1, a second aperture may be disposed in WR4-BR2, a third aperture may be disposed in WR3-BR3, a fourth aperture may be disposed in WR2-BR4, a fifth aperture may be disposed in WR1-BR5, and so forth. However, as may be understood, any patterns or locations may be utilized, such as zig-zag patterns between only two WR or BR rows, or other combinations.

Nonetheless, in embodiments, it may be desired to space apart adjacent apertures 470 in two or more BR or WR rows as described in the example above in order to minimize the occurrence of shorts. However, in embodiments, it may be desirable to include one aperture per bridge 320 in order to further control hole dissipation.

In embodiments, apertures 470 may be self-aligned between adjacent second source/drain regions 456 in a respective bridge connected row. As illustrated, second source/drain regions 456 may be utilized to align the apertures 470 with bridge 320. However, it should be understood that, in embodiments, other methods for forming the apertures 470 may be used as known in the art. For instance, the apertures 470 may be formed utilizing one or more methods for forming storage node contacts. Namely, in embodiments, a larger aperture than necessary for the contact may be formed, and an additional liner may be formed on an exterior of the aperture, as an example only.

While the apertures are illustrated as having a circular cross-section, it should be understood that other cross-sectional shapes are possible. In embodiments, the cross-sectional shape of the apertures 470 may be selected based upon the shape of shallow trench isolation 308. Nonetheless, in embodiments, the aperture size and shape may be selected so as to remove all, or a majority, of second dielectric material 332 from each respective shallow trench isolation 308 above bridge 320, while leaving protective liner 310 intact, or may only remove a portion of second dielectric material 332. Regardless of the shape and size of the aperture in a horizontal direction, the aperture should have a height sufficient to expose conductive material 440.

Nonetheless, after etching apertures 470, the exposed conductive material 440 and/or bridge 320 material undergoes a metallization process at operation 409. In embodiments, the metallization operation 409 may be a silicidation process, forming a body contact cap 472 as illustrated in FIG. 5F. For instance, a metal layer may be applied over conductive material 440 and/or bridge 320 material and exposed to a silicidation process. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting body contact cap 472 may be a metallized layer of any one or more of the above metals and the channel material, such as silicon. In such an example only, the cap 458 layer may be a titanium silicide, molybdenum silicide, or a combination thereof.

After formation of the body contact caps 472, a conductive metal shield 474 is formed in apertures 470 and over interlayer dielectric 468 at operation 410 as illustrated in FIG. 5G. In embodiments, the conductive metal shield 474 may be one or more of cobalt (Co), copper (Cu), nickel (Ni), ruthenium (Ru), manganese (Mn), silver (Ag), gold (Au), platinum (Pt), iron (Fc), molybdenum (Mo), rhodium (Rh), titanium (Ti), tantalum (Ta), silicon (Si), tungsten (W), or combinations thereof. In one or more embodiments, the conductive metal shield 474 is one or more of titanium (Ti), copper (Cu), cobalt (Co), tungsten (W), ruthenium (Ru), or a combination thereof.

Namely, by including a conductive metal shield 474 in apertures 470 in contact with body contact caps 472, and over the surface of interlayer dielectric 468, the one or more bridges 320 may now be placed in electrical contact with the body of semiconductor structure 500. Thus, the one or more walls 305/448 are no longer floating, reducing and/or completely eliminating the floating body effect due to conductive metal shield 474 serving as a body contact. For instance, in embodiments, a biasing potential may be applied to conductive metal shield 474, such as a zero voltage or slightly negative voltage, in embodiments, attracting any holes present to the top plate 476 of conductive metal shield 474 and at least partially, if not fully, moving out of the two or more walls 305.

However, due to the presence of a conductive material (e.g. conductive metal shield layer 474), the bit line contact must be isolated from conductive metal shield layer 474. Thus, operation 411 of forming a bit line contact includes isolation of the bit line contact from metal shield layer 474 in FIG. 5H. Namely, as illustrated, operation 411 can include applying a second interlayer dielectric 478 over conductive metal shield layer 474. The second interlayer dielectric 478 may include any one or more of the dielectric materials discussed above. As illustrated in FIG. 5H, the second interlayer dielectric 478 may be recessed to access at least one bit line 462. After formation of the recess, the conductive metal shield layer 474 may be recessed horizontally, and a plug dielectric material 482 is filled into the recess, electrically isolating the recess 481 from conductive metal shield 474. The plug dielectric material 482 may be formed from any one or more of the above discussed dielectric and/or liner materials utilizing any of the application techniques. However, in embodiments, the plug dielectric material 482 may be conformally filled into the recess. Nonetheless, as illustrated, the bottom of plug 482 has been removed (e.g. “punched out”), exposing the top portion 480 of one or more bit lines 462 while insulating the remainder of the recess from conductive metal shield layer 474.

Referring to FIG. 5I, after formation of plug 482 and etch out of the bottom of plug 482, bit line contact 484 may be formed by filling one or more conductive materials into recess 481. In embodiments, bit line contact 484 may be formed from the same material or a different material than bit line 462. Thus, in embodiments, the conductive material may be deposited by any suitable technique known in the art, such as one or more deposition or filing techniques discussed above. In some embodiments, the bit line contact 484 includes one or more of tungsten (W), ruthenium (Ru), iridium (Ir), platinum (Pt), rhodium (Rh) or molybdenum (Mo). In embodiments, the bit line 462 material is or is one or more of ruthenium or tungsten.

After formation of the bit line contact 484, the semiconductor structure 500 may re-enter a normal process flow for a vertical cell DRAM array, such as a 4F² DRAM array, and undergo one or more further processing steps. For instance, the semiconductor structure 500 may undergo contact redistribution, bonding pad formation, and/or copper contact formation. Nonetheless, semiconductor structure may exhibit a drastically reduced or even eliminated floating body effect due to the sharing of holes between channels in respective rows (e.g. rows WR1-WR5 parallel or in plane with word lines) and/or connection of each row to the substrate body.

Regardless of whether a body contact is utilized, the present technology may also provide for the formation of more than one p-type bridge. For instance, FIG. 6A may show an embodiment similar to FIG. 3G (e.g. after operation 206). However, FIG. 6A illustrates where the first and/or second recessing operation 201 and/or 204 including etching first dielectric material 306 to a height of less than or about 50% of the trench height, such as less than or about 45%, such as less than or about 40%, such as less than or about 35%, such as less than or about 30%, such as less than or about 25%, such as less than or about 20%, such as less than or about 15%, such as less than or about 20%, or any ranges or values therebetween. However, in embodiments, the height may be greater than 0% of the trench height so as to prevent overlap with a source/drain region and shorting as discussed above, such as greater than or about 5%, such as greater than or about 10%, or any ranges or values therebetween.

Namely, the present technology has surprisingly found that by utilizing more than one p-type bridge 320, holes, such as those formed from band-to-band tunneling, may be prevented from accumulating in the center of the channel, reducing polarity of the channel and reducing on current. Stated differently, by utilizing more than one p-type bridge, such as one or more bridges adjacent to each source/drain region, further reduction in gate induced drain leakage may be exhibited due at least in part to the location adjacent to source/drain contacts. Thus, in embodiments, such as embodiments where a further reduced word line voltage is desired, in addition to any of the other factors discussed above, more than one p-type bridge may be utilized. However, it should be clear that, in embodiments, any one or more of the methods and devices discussed herein are suitable for reducing gate induced leakage current and the floating body effect.

Nonetheless, as illustrated in FIG. 6B, in embodiments, operation 207 may optionally include filling a conductive material 340 over p-type bridge 320. Conductive material may be any material discussed in regards to conductive material 440 above and may be incorporated utilizing any one or more of the methods discussed in operation 406. Regardless of the conductive material 340 and/or method utilized, a dielectric material, which may be the same or different than first dielectric material 306, may fill the remainder of the shallow trench isolation.

As illustrated in FIG. 6C, the dielectric material 306 may then again be etched back to a second height that is less than a first height, as discussed in regards to operation 204, similar to FIG. 3G. The exposed sidewall 322 may be optionally cleaned as discussed above in regards to operation 205 and as illustrated in FIG. 3F. Similarly to FIG. 3G, FIG. 6C illustrates the formation of a second p-type bridge 321. Second p-type bridge 321 may be formed from the same material or a different material as p-type bridge 320, according to any one or more of the materials and doping levels discussed above. Furthermore, while two p-type bridges are illustrated in FIG. 6A, it should be clear that operations 204 to 207 may be repeated to form three p-type bridges, or more.

Regardless, in embodiments, a p-type bridge, such as second p-type bridge 321 may be formed adjacent to first end 307, so as to be adjacent to a second source/drain region. Thus, in embodiments, at least a second p-type bridge is formed in shallow trench isolation 308 at a height that is greater than or about 60% of a trench height, such as greater than or about 65%, such as greater than or about 70%, such as greater than or about 75%, such as greater than or about 80%, such as greater than or about 85%, such as greater than or about 90%, or any ranges or values therebetween. However, in embodiments, the height may be less than 100% of the trench height so as to prevent overlap with a source/drain region and shorting as discussed above, such as less than or about 95%, such as less than or about 90%, or any ranges or values therebetween.

Notwithstanding the height selected, a conductive material, which may be the same or different than conductive material 340 and/or 440, may be formed over the second p-type bridge 321. Moreover, similar to operation 207, a dielectric material, which may be the same or different than first dielectric material 306 may fill the remainder of shallow trench isolation 308. After filling, the structure 300 may undergo body contact formation as discussed above, or may re-enter a normal process flow for a vertical cell DRAM array, such as a 4F² DRAM array, and undergo one or more further processing steps. For instance, the semiconductor structure 300 may undergo contact redistribution, bonding pad formation, and/or copper contact formation. Nonetheless, semiconductor structure may exhibit a drastically reduced or even eliminated floating body effect due to the sharing of holes between channels in respective rows.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A vertical cell dynamic random-access memory (DRAM) array, comprising:
a plurality of bit lines arranged in a first horizontal direction;
a plurality of word lines arranged in a second horizontal direction;
a plurality of channels extending in a vertical direction that is generally orthogonal to the first horizontal direction and the second horizontal direction such that the plurality of bit lines intersect with a source/drain region of the plurality of channels, and the plurality of word lines intersect with gate regions of the plurality of channels; and
a p-doped bridge extending between a first channel of the plurality of channels and a second channel of the plurality of channels, wherein the first channel is spaced apart from the second channel in a row extending in the second horizontal direction.

2. The vertical cell dynamic random access memory (DRAM) array of claim 1, wherein the p-doped bridge has a doping level greater than or about 1.6 times a doping level of the first channel and the second channel.

3. The vertical cell dynamic random access memory (DRAM) array of claim 1, further comprising a shallow trench isolation defined between the first channel and the second channel, the shallow trench isolation having a height extending from a first end to a second end.

4. The vertical cell dynamic random access memory (DRAM) array of claim 3, wherein the p-doped bridge is disposed in the shallow trench isolation at about 20% to about 80% of the height of the shallow trench isolation.

5. The vertical cell dynamic random access memory (DRAM) array of claim 1, wherein the p-doped bridge is formed from crystalline silicon.

6. The vertical cell dynamic random access memory (DRAM) array of claim 1, further comprising at least a third channel of the plurality of channels spaced apart from the second channel in the row extending in the second horizontal direction, wherein a second p-doped bridge extends between the second channel and the third channel.

7. The vertical cell dynamic random access memory (DRAM) array of claim 3, further comprising a body contact in electrical connection with the p-doped bridge.

8. The vertical cell dynamic random access memory (DRAM) array of claim 7, wherein the body contact is connected to a biasing voltage source and/or further comprising a bit line contact electrically connected to one or more of the plurality of bit lines, wherein the bit line contact is electrically isolated from the body contact.

9. The vertical cell dynamic random access memory (DRAM) array of claim 1, further comprising a second p-doped bridge extending between the first channel of the plurality of channels and the second channel of the plurality of channels.

10. A vertical cell dynamic random access memory (DRAM) array, comprising:
a plurality of bit lines arranged in a first horizontal direction;
a plurality of word lines arranged in a second horizontal direction;
a first plurality of spaced apart channels in a first row extending in the second horizontal direction;
a second plurality of spaced apart channels in a second row extending in the second horizontal direction, spaced apart from the first row; and
a plurality of p-doped bridges extending between adjacent channels in the first row and between adjacent channels in the second row;
wherein each of the channels extends in a vertical direction that is generally orthogonal to the first horizontal direction and the second horizontal direction such that the plurality of bit lines intersect with a source/drain region of the plurality of channels, and the plurality of word lines intersect with gate regions of the plurality of channels.

11. The vertical cell dynamic random access memory (DRAM) array according to claim 10, further comprising a shallow trench isolation defined between adjacent channels in each row, the shallow trench isolation having a height extending from a first end to a second end.

12. The vertical cell dynamic random access memory (DRAM) array according to claim 10, further comprising second shallow trench isolations between adjacent channels in the first row and the second row, and a gate formed along an exterior surface of the second shallow trench isolations.

13. The vertical cell dynamic random access memory (DRAM) array according to claim 11, further comprising a conductive material overlying each p-doped bridge.

14. The vertical cell dynamic random access memory (DRAM) array according to claim 13, further comprising at least a second plurality of p-doped bridges extending between adjacent channels in the first row and between adjacent channels in the second row.

15. A method of forming a vertical cell dynamic random-access memory (DRAM) array, comprising:
etching a substrate to form one or more shallow trench isolations and a plurality of vertically extending channels having a first source/drain region at a second end of the vertically extending channels;
forming a dielectric material in the one or more of the shallow trench isolations;
recessing the dielectric material to a first height in the one or more shallow trench isolations;
forming a protective liner in one or more shallow trench isolations;
bottom punching the protective liner;
recessing the dielectric material to a second height in the one or more shallow trench isolations below the first height;
forming a p-doped bridge in the one or more shallow trench isolations, wherein the p-doped bridge contacts a first sidewall and a second sidewall of the one or more shallow trench isolations, exposed by the recessing to the second height.

16. The method of claim 15, further comprising filling a dielectric material into the one or more shallow trench isolations above the p-doped bridge.

17. The method of claim 15, further comprising forming a conductive material over the p-doped bridge.

18. The method of claim 17, comprising forming the p-doped bridge epitaxially and depositing the conductive material over the p-doped bridge.

19. The method of claim 17, comprising etching first apertures in at least a portion of the one or more shallow trench isolations from an exposed surface of the vertical cell dynamic random access memory (DRAM) array to the conductive material in the one or more shallow trench isolations, metallizing a top surface of the conductive material, and forming a conductive metal shield in the aperture and over an exposed surface of the vertical cell dynamic random access memory (DRAM) array.

20. The method of claim 19, further comprising forming an interlayer dielectric over the conductive metal shield, etching a second aperture through the interlayer dielectric to a bit line formed over a second source/drain region formed at a first end of the vertically extending channels, and isolating the aperture from the conductive metal shield.
